(19) United States
(12) Patent Application Publication
(10) Pub. No.: US 2007/0269611 A1
(43) Pub. Date: Nov. 22, 2007

(54) Systems and methods of combinatorial synthesis

(75) Inventors: Xiao-Dong Xiang, Danville, CA (US); Gang Wang, San Jose, CA (US); Wei Shan, Fremont, CA (US); Jonathan Melman, San Mateo, CA (US)

Correspondence Address: BUCHANAN, INGERSOLL & ROONEY PC, POST OFFICE BOX 1404, ALEXANDRIA, VA, 22313-1404, US

(73) Assignee: Intematix Corporation, Fremont, CA (US)

(21) Appl. No.: 11/726,742

(22) Filed: Mar. 22, 2007

Related U.S. Application Data
(60) Provisional application No. 60/787,931, filed on Mar. 31, 2006.

(51) Int. Cl. C23C 14/00; G01N 21/29; G01N 31/22; B05D 3/00; C23C 14/30; C23C 14/28; B29C 71/04; C23C 16/00

(52) U.S. Cl. 427/555; 422/57; 427/532; 427/595; 427/596; 427/248.1; 204/298.11; 204/298.12

(57) ABSTRACT

Disclosed are methods to synthesize new functional materials in an effective and efficient way. These methods include physical vapor deposition and laser-assisted epitaxial growth capable of synthesizing materials comprising a plurality of precursors with similar or dissimilar chemical and/or physical properties. The designed materials are formed during the combinatorial synthesis without the necessity of post-deposition furnace heating to thermally activate simultaneous reaction and diffusion of precursor multilayers. Modulated photoreflectance spectroscopy may be used to screen regions of the library to assess deposition conditions.

### CROSS REFERENCE TO RELATED APPLICATIONS

This application claims the benefit of priority to U.S. Provisional Patent Application No. 60/787,931, filed Mar. 31, 2006, the specification and drawings of which are incorporated herein by reference.

### BACKGROUND OF THE INVENTION

1. Field of the Invention

Embodiments of the present invention are directed in general to systems and methods of synthesizing functional materials comprising a plurality of chemically distinct precursors. More specifically, the precursors are chemically distinct and a great variety of combinations of atomic compositions are provided.

2. Description of the Related Art

Combinatorial synthesis is a time-efficient and cost-effective technique for developing new materials. By depositing a desired number of chemical elements in various combinations and at the desired atomic mole fractions of the respective elements, new functional materials may be discovered. The chemical member elements may be deposited either discretely or continuously on either single substrates or multiple substrates. Using such a combinatorial method, the composition of the constituents that yields the desired performance may be discovered and identified at a fast and efficient rate.

Combinatorial materials may be synthesized as diverse and/or discrete compositional libraries such that specific regions or segments of a larger compositional combination may be examined. The libraries may also be produced to have a continuous variation in composition, much as a “real life” representation of a theoretical (materials science) phase diagram. If three elements are non-stoichiometrically and continuously varied in a deposition, for example, a library comprising a ternary phase diagram may be created literally, a physical version of the theoretical counterpart then exists. These phase diagrams may be used to map out phase boundaries so that important and relevant phase regions of interest may be identified (and exploited).

To date, the vast majority of combinatorial synthesis using physical vapor deposition has been carried out using a two step process. The first step involved depositing a multilayer on a substrate from two or more precursor sources that were spatially separated and chemically distinct. The result was a stacked thin film having a composition gradient that existed in a direction going through the different layers. Typically, a synthesis step such as this would employ hardware that might have included continuously moving shutters, or a group of discrete chips each with predetermined concentrations of respective precursors by deploying discrete shadow masks.

A second step involved a post-deposition thermal annealing process, typically in a furnace, to activate simultaneous reaction and stimulate inter-diffusion between the deposited constituents. Such annealing would produce the desired alloy and/or compound. A variant of this second step preheated a substrate to an elevated temperature with the hope of providing the initial thermal activation required for reaction between the constituents, again encouraging inter-diffusion between the constituent layers as the deposition was occurring.

Since these processes are thermally activated, simultaneous reaction and inter-diffusion are inevitable in this type of a combinatorial synthesis (especially when physical vapor deposition is used as the synthesis method) because a multilayer stack of precursors will not substantially inter-diffuse unless the stack is thermally annealed. The temperature environment that promotes and controls the reaction and/or the inter-diffusion plays a key role in determining the final characteristic(s) of the material(s) in terms of stoichiometry and phase structure(s), as well as the materials' chemical, electrical, optical, and magnetic properties.

What is needed in the art is a method of combinatorial synthesis capable of conducting in situ thermal annealing either during, or at some time subsequent to the deposition; in other words, a capability of carrying out specific treatments and processing to specific and desired regions of the growing film(s). Additionally, methods of carrying out the thermal annealing step in a combinatorial manner are also needed, similar to the way in which the library was fabricated in a combinatorial manner. Specifically, methods of optical mapping and/or screening the combinatorial library are needed that involve techniques of photoreflectance.

### SUMMARY OF THE INVENTION

Embodiments of the present invention are directed to methods of combinatorial synthesis that produce functional materials comprising a plurality of chemical constituents (which may be chemical elements) with either continuously changing mole fractions of the constituent, or else discretely varied compositions. A non-contacting heating mechanism provides the thermal activation energy necessary for promoting and controlling reaction(s) amongst the deposited precursors. Diffusion of precursors from different sources is used to carry out in situ thermal annealing in a highly specific and regional manner. The heating may be spot or site selective, so that the desired thermal annealing may be effected in keeping with the combinatorial concept. The presently disclosed methods may effectively render the synthesized materials the final products of design.

### BRIEF DESCRIPTION OF THE DRAWINGS

FIG. 1 is a schematic diagram showing the operating principle of the presently disclosed system for carrying out combinatorial synthesis;

FIG. 2 is an illustration of a selective laser heating scheme for thermally-activating the desired inter-diffusion and annealing using a 4×4 combinatorial materials matrix as an example;

FIG. 3 is a schematic diagram showing an exemplary configuration of high-throughput optical mapping and screening using photoreflectance, according to the present embodiments; and

FIG. 4 shows how an exemplary measurement step may be incorporated into the present methods; specifically, how photoreflectance may be used to map optical response from a sample comprising a combinatorially-produced, real-materials-based phase diagram (not theoretical or diagrammatic).

### DETAILED DESCRIPTION OF THE INVENTION

Disclosed herein are methods of synthesizing combinatorial libraries of functional materials, and continuous-gradient materials layers that correspond in the real world to what a theoretical or constructed phase diagram would be on paper. In other words, the presently synthesized “continuous-gradient” libraries are the physical representation and construction entirely analogous to the theoretically constructed phase diagram on paper. In one embodiment of the present invention, physical vapor deposition is used to synthesize the combinatorial library, either as an array of discrete members, or in continuous-gradient form. The compositional gradient in the combinatorial library may run in either x and y-directions, that is, parallel to the surface of the substrate, or in the z-direction, normal to the surface of the substrate. The x, y, and z-directions may be orthogonal to one another, but they do not have to be.

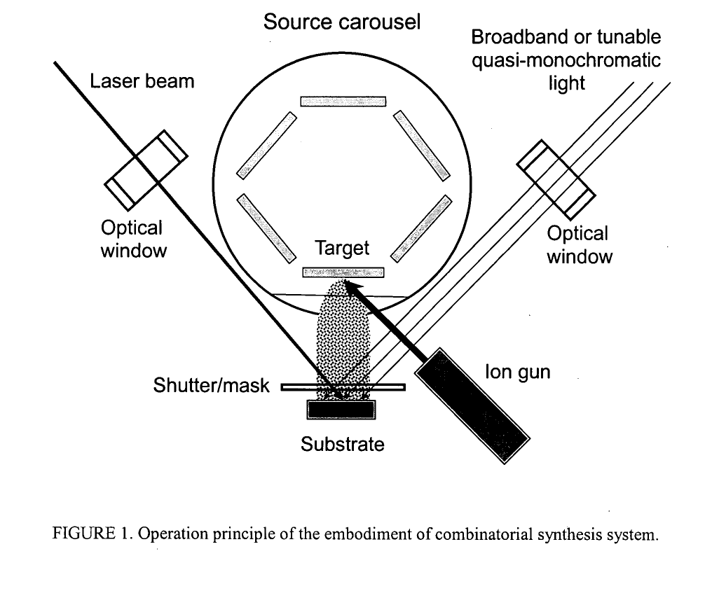

In one embodiment of the present invention, at least one chamber of a physical deposition system houses a shrouded source carousel on which a plurality of source targets may be loaded, a substrate holder with a movable shutter/mask combination in front, and an ion gun for supplying ions to the sputtering targets to generate the flux of precursor atoms. The chamber housing this hardware may be referred to as the “main” chamber of the physical deposition system (to be distinguished, for example, from load locks or accessory chambers attached to a main chamber for performing a variety of preparation, synthesis, and analytical functions). Two transparent windows on the main chamber provide optical access for lasers and/or light from a broadband source to the substrate area. The broadband source may be a quasi-monochromatic light source. The operating principle of such a physical deposition system is shown in FIG. 1.

The system is designed to synthesize a multi-precursor, continuous-gradient compositional library, analogous to the theoretically or experimentally constructed phase diagram on paper, the library useful for investigating the complex relationship(s) between composition, crystalline structure, and physical properties of the multi-component system. Particularly important in this disclosure is that the library may be synthesized in a single deposition. The continuous-gradient library may be fabricated using linear shutters in the main chamber of the deposition system that move at a controlled rate during the deposition of each precursor.

In one example of the present embodiments, a ternary phase diagram may be generated by the graded deposition of three precursors. This method has available to it precise control of molar stoichiometries within very small areas or regions of the substrate because the compositional variation is directly correlated to the dimensions of the sample in a linear scale. The present system may also employ shadow masks to fabricate a combinatorial library comprising spatially separated and/or discrete depositions on a single substrate. Such discrete-member libraries may be referred to as “material chips,” and have been described in general by authors Y. K. Yoo and X. D. Xiang in Combinatorial Materials Synthesis, X. D. Xiang and I. Takeuchi, eds. (Marcel Dekker, New York, 2003), Ch. 8.

In such a device, each chip has its own distinct combination of precursors, achieved in part by maintaining the deposition chamber at an ultra-high vacuum (e.g., better than about 10⁻¹⁰ Torr) to prevent oxidation of the deposited layers. Oxygen contamination is detrimental to metallic alloys and non-oxide compounds such as may be found in semiconducting materials. Even if the synthesis of a library comprising oxides is the goal, this ultra-high vacuum condition is still desirable because the oxygenation reaction may be easily achieved by post-deposition, thermally activated reaction and inter-diffusion of precursor layers with an oxygen over pressure.

Also illustrated schematically in FIG. 1 is a laser beam directed through an optical window to illuminate the substrate in a particularly targeted area or region of the substrate. The laser beam provides laser heating that thermally activates reaction/diffusion between the layers of amorphous precursors that had been deposited onto the substrate in a previous step. The laser heating may be applied at any time; e.g., during a first deposition; after the first deposition but prior to a second deposition; during a second deposition, etc. In other words, laser heating may be carried out simultaneously with the materials deposition of any deposition step to assist the lateral diffusion of precursor atoms once they have attached to the substrate surface. Alternatively, laser heating may be applied immediately after the deposition of a stack of multiple layers to activate interaction and diffusion between atoms within any one layer, or between atoms of different layers.

In some embodiments, the effectiveness and the efficiency of laser heating and its capability to effect thermal annealing depends on the modes in which the laser is being used; i.e. the modes including pulsed and continuous-wave (CW) modes, as well as the type of the laser, and associated functional parameters associated with laser operation. The laser-types that may be used in the present embodiments include, but are not limited to, excimer lasers, gaseous lasers, solid state lasers, semiconductor laser diodes, dye lasers, oscillators, and harmonic generators pumped by any of the aforementioned lasers. The functional parameters of the lasers being used include, but are not limited to, the wavelength of the laser, the power density that the laser imparts to the sample, the exposure time of the illumination, and the pulse width, repetition rate, and the energy fluence of a pulsed laser.

In one embodiment a pulsed laser is preferred because its heating effect can induce melting of a stack of as-deposited amorphous precursor multilayers, followed by a rapid epitaxial growth stage that yield crystallized materials in the combinatorial library. Specific events that may occur with this pulsed laser heating and induced melting technique are essentially: 1) absorption of the laser radiation, 2) melting of the amorphous layers, and 3) subsequent and rapid epitaxial growth. Epitaxial growth may be seeded at the solid-liquid interface by something in the bulk that is crystalline, such as, for example a substrate that is itself crystalline. Such growth occurs in a manner similar to liquid phase epitaxy, the difference being that in the present embodiments the process occurs on a much shorter time scale (typically between 10⁻⁸-10⁻⁶ seconds).

The general principles governing this kind of deposition have been discussed in Laser and Electron Beam Processing of Materials, C. W. White and P. S. Peercy, eds. (Academic Press, New York, 1980); and by J. S. Williams in Laser Annealing of Semiconductors, J. M. Poate and J. W. Mayer, eds. (Academic Press, New York, 1982), p. 385. These references disclose that pulsed laser melting (PLM) of amorphous layers of GaAs formed by high dose implantation can cause the layers to be re-grown into nearly perfect single crystals with electrical activities of the dopants far superior to that which could be achieved by furnace annealing. Synthesis of diluted ferromagnetic Ga₁₋ₓMnₓAs with Curie temperatures as high as 80K using the PLM process has recently been demonstrated as well; see, for example, an article by M. A. Scarpulla, K. M. Yu, O. Monteiro, M. Pillai, M. C. Ridgway, M. J. Aziz, and O. D. Dubon in Appl. Phys. Lett. 82, 1251 (2003). Due to the rapid crystallization rate, this approach is very effective for generating well mixed alloys from stacked multilayers of combinatorial materials to a level well above the solubility limit.

Another advantage of laser heating to induce thermal activation and thermal annealing is that, by using the appropriate optics, the spot size of the laser beam may be manipulated while maintaining a substantially constant power density. By controlling spot size, the thermal activation/annealing that results from the laser heating may be conducted selectively and individually if desired, on any one individual chip, or on a group of individual chips, or on a specific region of a continuous-gradient combinatorial library. Furthermore, the spot size of the laser beam may be directed in various patterns of the continuous-gradient phase diagram such that different regions of the library receive different doses.

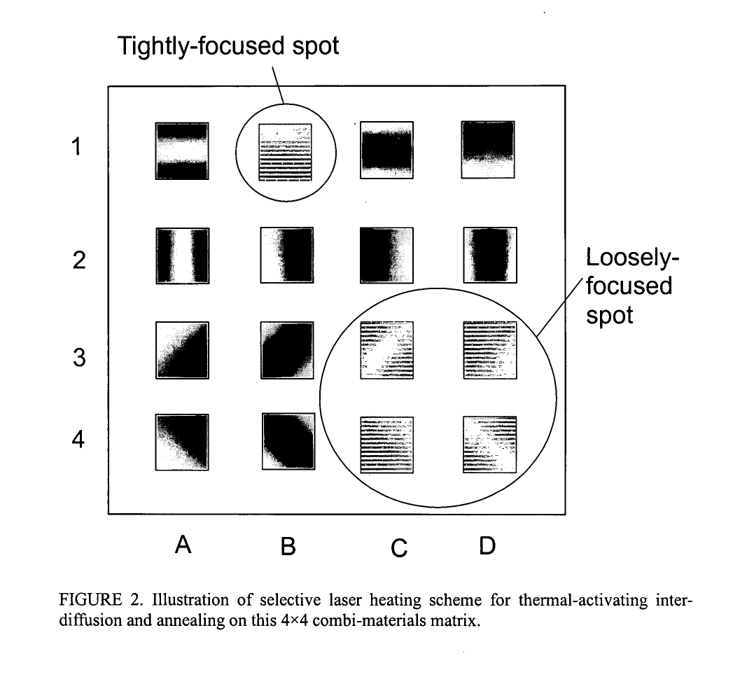

These concepts are illustrated in FIG. 2, which is a diagram of a selective laser heating scheme for thermally-activating the desired inter-diffusion and annealing of a 4×4 combinatorial materials matrix. The choice of 4×4 for the size of the matrix is purely exemplary. Referring to FIG. 2, the 4×4 combinatorial materials matrix has been hypothetically deposited on a substrate and is ready to be subjected to laser heating. The laser beam size can be varied to have a focal spot small enough to cover just a single element (chip) of the matrix so that thermal annealing by laser heating is performed only on that particularly selected chip. This is illustrated in FIG. 2 at the array member labeled B1, and labeled with the text “tightly focused spot.” Such selective heating may be applied to each of the elements of the matrix, one by one, by scanning the laser beam across the matrix with the spot size of the laser beam just slightly larger than the size of each chip.

Alternatively, the spot size may be increased such that more than one chip is heated at any one time. This is illustrated in the bottom right corner of FIG. 2, where the spot size of the laser beam has been increased such that the four cells C3, D3, C4, and D4 are simultaneously heated. It is contemplated that with additional optical hardware, the spot size of the laser beam need not be circular (in other words, it could be oval shaped) such that three chips in a line (either row or column) are simultaneously heated. The principle applies to a selected region that includes more than one element but not all the elements on the matrix.

It will also be recognized by one of skill in the art that it is not necessary to deposit the entire matrix before laser heating any of the members of the matrix or any regions of the library. In other words, it is possible to have the “A” column of members A1, A2, A3, and A4 deposited, and then have the A column members subjected to laser heating while the “B” column is being deposited. This is one reason for configuring the deposition chamber to have multiple accessory ports on and chambers attached to the main chamber, such that multiply varied operations may be simultaneously conducted.

During the laser thermal-activating, diffusion, and/or annealing step(s), the energy fluence of the laser pulses and the exposure time (which may be quantified by the number of pulses) is controllable. The conditions are controllable whether they are applied separately to individual array members, or collectively to several array members at a time. The present method offers additional flexibility to combinatorial synthetic methods by offering potentially different processing conditions for any regions of the materials deposited on a substrate, even if the deposited material is in the form of a continuous-gradient film. This is especially convenient when the different array members, or chip locations, for which different heating conditions is desired, have all been deposited on a single substrate.

Alternatively, the method is amenable for laser-assisted thermal annealing when similar (or even identical) heating conditions are desired for each member of an array of combinatorial materials chips, deposited on a single substrate, with the beam spot size expanded to cover the entire matrix. In this latter approach, all of the elements on the matrix may be illuminated uniformly. Additionally, when identical thermal processing conditions are desired, the members of the array do not have to be illuminated at the same time; they may be illuminated individually. Of course, combinations of both techniques are possible, whereby different thermal conditions are used for several members of the array on one region of the substrate, and substantially identical conditions are used for more than one members of the array.

Post-deposition thermal annealing to activate reactivity within the as-deposited and stacked multilayers, as well as to promote inter-diffusion of materials within those multilayers, may be carried out on different multilayers on the same substrate. Again, thermal annealing conditions may be varied for different regions of the same multilayer stack. This is an important aspect of the present embodiments, because such a treatment is equivalent to different runs of a combinatorial synthesis if the selective regional laser heating is conducted using a varying set of parameters for each region of the multilayer stack.

Another embodiment of the present invention is the high-throughput optical mapping and screening that may be carried out in situ. Optical reflection, photoluminescence, and Raman scattering have been routinely employed to assess the properties, in most cases of uniformly distributed homogeneous materials, the films and/or materials having very small compositional fluctuations. In the case of a combinatorially synthesized array or continuous-gradient layer/multilayer, however, the sentivity and effectiveness of such optical methods to assess materials properties may pose difficulties. For example, high throughput energy-gap mapping using reflection measurement can be time-consuming, and photoluminescence and Raman scattering measurements can be difficult to obtain due to the continuous variation in the composition and the relatively low crystalline quality (particularly in the case of polycrystalline films). These drawbacks may be overcome by using photoreflectance measurements, which employ phase-sensitive modulation methods with higher detection sensitivity.

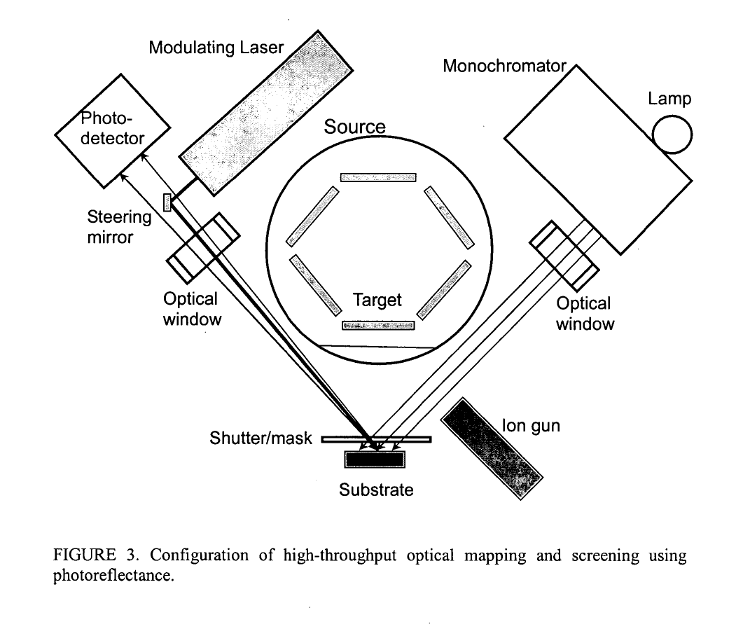

The present methods contemplate the use of photoreflectance to assess (screen) the material properties of a combinatorially synthesized library, in situ and optionally in real time. FIG. 3. shows an exemplary configuration of a high-throughput optical mapping and screening system according to the present embodiments. Photoreflectance is a form of modulation spectroscopy with a differential detection capability, achieved by photo-injecting electrons to the conduction band of a semiconducting or insulating sample or region in the library. Referring to FIG. 3, the optics of such a measurement system comprise a quasi-monochromatic beam dispersed by a monochromator to illuminates a sample of the library, the sample acting as a probe beam. A laser beam modulated by an optical chopper (the optical chopper not shown in FIG. 3) is directed onto on the sample to provide the modulation. A photodetector connected to a phase-sensitive lock-in amplifier detects the spectral response of modulated signals reflected from the sample. The periodically modulated light beam probes differential changes manifested as sharp, derivative-like line shapes in a slowly varying reflection spectrum. The technique is suitable for use with broad and hard-to-resolve spectral features.

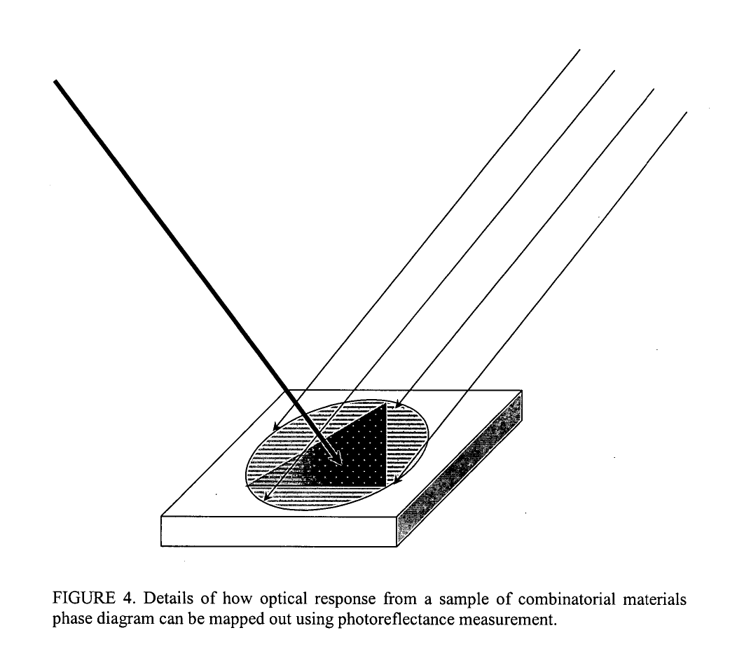

FIG. 4 illustrates how optical mapping and screening of sample chips in combinatorially generated materials phase diagrams (continuous-gradient libraries) may be accomplished with photoreflectance. With the incident quasi-monochromatic light uniformly illuminating the entire chip, the modulated laser beam is focused onto a small spot within the chip to generate a differential reflectance signal from that spot. Although the photodetector receives substantially all of the reflected probe light from the entire chip, only the differential signal from the spot being laser modulated is picked up by a phase-sensitive lock-in detection system. A computer controlled mirror steers the modulating laser beam across the sample chip so that the optical response from various spots on the chip can be quickly and accurately measured. Optical transition energy related to the fundamental band gap as a function of position on the chip is mapped out and correlated to the growth conditions for the library.

What is claimed is:

1. A method of synthesizing a combinatorial library of materials, the method comprising:
(a) depositing a first chemical precursor of the library onto a substrate;
(b) depositing a second chemical precursor of the library onto the substrate; and
(c) providing radiation at first to only a portion of the substrate to thermally anneal and/or inter-diffuse the two precursors in the radiated region of the substrate, thereby generating a combinatorial library of new materials in the region of the substrate exposed to the radiation.

2. The method of claim 1, wherein at least one of the deposition steps and the radiation steps occur substantially simultaneously.

3. The method of claim 1, further including a second radiation step to provide radiation to a different region of the substrate than the region that was exposed to radiation in the first radiation step.

4. The method of claim 3, wherein the operating conditions of the second radiation step are different from the operating conditions of the first radiation step.

5. The method of claim 1, wherein the combinatorial library comprises an array of discrete members.

6. The method of claim 1, wherein the combinatorial library is a gradient of continuously varying compositions along directions parallel to the surface of the substrate onto which the precursors were deposited.

7. The method of claim 1, wherein the step providing radiation to the substrate is carried out using a laser beam.

8. The method of claim 4, wherein the laser beam is operated in a mode selected from the group consisting of pulsed and continuous-wave (CW) modes.

9. The method of claim 1, further including the step of screening different regions of the library using photoreflectance.

10. A method of synthesizing a combinatorial library of materials, the method comprising:
(a) delivering a first precursor of a first material and a first precursor of a second material to first and second regions of a substrate, respectively;
(b) delivering a second precursor of the first material and a second precursor of the second material to the first and second regions of the substrate, respectively;
(c) providing radiation to the first region of the substrate to thermally anneal and/or inter-diffuse the first and second precursors of the first material to form a processed first material; and
(d) providing radiation to the second region of the substrate to thermally anneal and/or inter-diffuse the first and second precursors of the second material to form a processed second material;
wherein the processed first and second materials comprise two members of the combinatorial library.

11. The method of claim 10, wherein the step providing radiation to the first region of the substrate occurs substantially simultaneously with the delivering of the second precursor of the first material.

12. The method of claim 11, further including a step of screening the combinatorial library.

13. The method of claim 12, wherein the screening is carried out by photoreflectance.

14. An apparatus for synthesizing a combinatorial library, the apparatus comprising:
a reaction chamber containing a shrouded source carousel on which a plurality of source targets is located;
a substrate holder for holding a substrate onto which the library is deposited, the substrate holder including a movable shutter/mask placed between the substrate and the source carousel for controlling the flux from the source targets;
an ion source for providing ions to the source targets, thereby generating a flux of precursor materials that travel to the substrate;
a first transparent window in the reaction chamber for allowing radiation from a radiation source placed outside the reaction chamber to illuminate and provide energy to the substrate;
a second transparent window in the reaction chamber for allowing radiation selected from the group consisting of a broadband source and a quasi-monochromatic source to illuminate the substrate.

15. The apparatus of claim 14, wherein the apparatus is configured to synthesize a continuous-gradient combinatorial library.

16. The apparatus of claim 14, further including a modulating laser, a photodetector, and monochromator for optical mapping and screening of the combinatorial library.
